(19) United States
(12) Patent Application Publication
(10) Pub. No.: US 2026/0212066 A1
(43) Pub. Date: Jul. 23, 2026

(54) SPATIAL RELATIONSHIP ANALYZING DEVICE FOR HEATWAVE VULNERABILITY AND VULNERABLE CLASS DISTRIBUTION AREA ACCORDING TO URBAN HEAT ISLAND AND METHOD THEREOF

(71) Applicant: International Center for Urban Water Hydroinformatics Research & Innovation, Incheon (KR)

(72) Inventors: Seung Kwon JUNG, Incheon (KR); Da Som HUR, Incheon (KR)

(73) Assignee: International Center for Urban Water Hydroinformatics Research & Innovation, Incheon (KR)

(21) Appl. No.: 19/090,187

(22) Filed: Mar. 25, 2025

(30) Foreign Application Priority Data
Jan. 22, 2025 (KR) 10-2025-0009286

(51) Int. Cl. G06F 30/20; G06F 16/901

(52) U.S. Cl. CPC G06F 30/20; G06F 16/901

(57) ABSTRACT

A spatial relationship analyzing device includes a data collection unit configured to collect satellite image data, vulnerable class population distribution data and heatwave shelter facility location data; a DB construction unit configured to construct land surface temperature data, vulnerable class population data and heatwave shelter facility number data in a land surface temperature DB, a vulnerable class population DB and a heatwave shelter facility number DB; a heatwave vulnerable area and vulnerable class distribution area assessment unit configured to calculate frequency of daily land surface temperature equal to or higher than a predetermined temperature for each grid unit, and generate a vulnerable class and heatwave shelter facility distribution; a spatial correlation analysis unit configured to analyze local spatial autocorrelation on the basis of heatwave occurrence frequency, and calculate a local spatial autocorrelation index; and a spatial relationship evaluation unit configured to assess a facilities targeting vulnerable class location index.

### BACKGROUND

### 1. Technical Field

The present disclosure relates to a heatwave vulnerable area analysis and management technology, and more specifically, to a spatial relationship analyzing device for heatwave vulnerability and a vulnerable class distribution area according to an urban heat island that calculates daily land surface temperature using satellite image data, calculates an urban heat island area through local spatial autocorrelation analysis based on the land surface temperature, and reflects a location analysis result by analyzing heatwave vulnerability, the proportion of vulnerable population and the proportion of heatwave shelter facilities in welfare facilities for each predetermined area unit, and a method thereof.

### 2. Related Art

As urbanization progresses in Korea and around the world, climate changes unique to urban areas that are different from rural areas are occurring. Among the climate changes in urban areas, the temperature in urban areas is rising compared to nearby rural areas, and this is supposed to be due to the urban heat island effect.

The urban heat island phenomenon is known to have direct and indirect negative effects on human health and quality of life, and as the temperature rise in urban areas is expected to worsen in the future due to climate changes, it is necessary to identify the urban heat island phenomenon, analyze vulnerable areas, and establish countermeasures.

In particular, the urban heat environment has worsened due to global warming in recent years, causing social and economic problems. Therefore, many local governments across the country are making efforts to improve the urban heat island phenomenon by promoting greening projects such as creating forests and parks.

However, since the survey work on the land surface temperature by area and the survey work on the average daily maximum temperature during a relevant period were both dependent on on-site surveys by investigators, there was a problem that a wide-ranging survey on the thermal environment of the city is not properly conducted. Although it is possible to consider installing an automatic weather system (AWS) in each area, this would be possible when investigating specific or narrow areas, and the installation cost would increase significantly when investigating a wide area, making the automatic weather system practically unusable.

Therefore, it is difficult to grasp the heat distribution characteristics of the entire city using conventional technology, and it is impossible to judge the suitability by linking the heat distribution characteristics with an urbanized area or a heatwave shelter. Thus, there is a problem that it is difficult to effectively establish urban planning with respect to the heat distribution characteristics.

### SUMMARY

An object of the present disclosure is to provide a spatial relationship analyzing device for heatwave vulnerability and a vulnerable class distribution area according to an urban heat island that is capable of analyzing the spatial relationship of heatwave vulnerability and a vulnerable class distribution area by an urban heat island phenomenon through calculating daily land surface temperature using satellite image data, calculating an urban heat island area through local spatial autocorrelation analysis based on the land surface temperature and reflecting a location analysis result by analyzing heatwave vulnerability, the proportion of vulnerable population and the proportion of heatwave shelter facilities in welfare facilities for each predetermined area unit, and a method thereof.

Objects to be achieved by the present disclosure are not limited to the objects mentioned above, and other objects not mentioned above may be clearly understood by those skilled in the art from the following description.

In an embodiment, a spatial relationship analyzing device for heatwave vulnerability and a vulnerable class distribution area according to an urban heat island may include: a data collection unit configured to collect satellite image data to calculate land surface temperature, collect vulnerable class population distribution data from a predetermined external population DB, and collect heatwave shelter facility location data from a predetermined external facility DB; a DB construction unit configured to store and construct land surface temperature data, vulnerable class population data and heatwave shelter facility number data outputted from the data collection unit, in a land surface temperature DB, a vulnerable class population DB and a heatwave shelter facility number DB, respectively; a heatwave vulnerable area and vulnerable class distribution area assessment unit configured to calculate the frequency of daily land surface temperature equal to or higher than a predetermined temperature for each predetermined grid unit, and generate a vulnerable class and heatwave shelter facility distribution for the corresponding grid unit; a spatial correlation analysis unit configured to analyze local spatial autocorrelation on the basis of heatwave occurrence frequency, and calculate a local spatial autocorrelation index; and a spatial relationship evaluation unit configured to assess a facilities targeting vulnerable class location index using a spatial vulnerability index for populations, a heatwave shelter facilities location index and the local spatial autocorrelation index.

According to one aspect of the present disclosure for achieving the objects and other features of the present disclosure, there is provided that the facilities targeting vulnerable class location index FVLI is assessed according to the following equation FLVI=0.3*SVP+0.3*SF+0.4*LS where SVP is a spatial vulnerability index for populations, SF is a heatwave shelter facilities location index, and LS is a local spatial autocorrelation index.

According to one aspect of the present disclosure for achieving the objects and other features of the present disclosure, there is provided that the spatial vulnerability index for populations SVP is assessed according to the following equation

$$SVP = \frac{( \frac{{P}_{ji}}{{p}_{jt}} )}{( \frac{{P}_{ti}}{{P}_{tt}} )}$$

where pji is the number of vulnerable population in a grid j, pjt is the total number of population in the grid j, Pti is the number of vulnerable population in an entire city, and Ptt is the total number of population in the entire city.

According to one aspect of the present disclosure for achieving the objects and other features of the present disclosure, there is provided that the heatwave shelter facilities location index SF is assessed according to the following equation

$$SF = \frac{( \frac{{h}_{ji}}{{h}_{jt}} )}{( \frac{{S}_{ti}}{{S}_{tt}} )}$$

where hji is the number of vulnerable population in a grid j, hjt is the number of heatwave shelter facilities in the grid j, Sti is the number of vulnerable population in an entire city, and Stt is the number of heatwave shelter facilities in the entire city.

According to one aspect of the present disclosure for achieving the objects and other features of the present disclosure, there is provided that the local spatial autocorrelation index LS is assessed using land surface temperature of a corresponding grid area and land surface temperature of a surrounding grid area, and the average value of land surface temperatures of eight grid areas surrounding the corresponding grid area is assessed as the land surface temperature of the surrounding grid area.

In an embodiment, a spatial relationship analyzing method for heatwave vulnerability and a vulnerable class distribution area according to an urban heat island may include: a data collection act of collecting satellite image data to calculate land surface temperature, collecting distribution data of vulnerable class population from a predetermined external population DB, and collecting heatwave shelter facility location data from a predetermined external facility DB; a DB construction act of storing and constructing land surface temperature data, vulnerable class population data and heatwave shelter facility number data generated in the data collection act, in a land surface temperature DB, a vulnerable class population DB and a heatwave shelter facility number DB, respectively; a heatwave vulnerable area and vulnerable class distribution area assessment act of calculating the frequency of daily land surface temperature equal to or higher than a predetermined temperature for each predetermined grid unit, and generating a vulnerable class and heatwave shelter facility distribution for the corresponding grid unit; a spatial correlation analysis act of analyzing local spatial autocorrelation on the basis of heatwave occurrence frequency, and calculating a local spatial autocorrelation index; and a spatial relationship evaluation act of assessing a facilities targeting vulnerable class location index using a spatial vulnerability index for populations, a heatwave shelter facilities location index and the local spatial autocorrelation index.

According to the spatial relationship analyzing device for heatwave vulnerability and a vulnerable class distribution area according to an urban heat island and the method thereof, it is possible to analyze the spatial relationship of heatwave vulnerability and a vulnerable class distribution area by an urban heat island phenomenon through calculating daily land surface temperature using satellite image data, calculating an urban heat island area through local spatial autocorrelation analysis based on the land surface temperature and reflecting a location analysis result by analyzing heatwave vulnerability, the proportion of vulnerable population and the proportion of heatwave shelter facilities in welfare facilities for each predetermined area unit.

### BRIEF DESCRIPTION OF THE DRAWINGS

FIG. 1 is a block diagram showing a spatial relationship analyzing device for heatwave vulnerability and a vulnerable class distribution area according to an urban heat island according to an embodiment of the present disclosure.

FIG. 2 is a flowchart showing spatial relationship analysis for heatwave vulnerability and a vulnerable class distribution area according to an urban heat island according to an embodiment of the present disclosure.

FIG. 3 is a flowchart showing data collection of a data collection unit according to an embodiment of the present disclosure.

FIG. 4 is a diagram showing an example of a DB construction unit according to an embodiment of the present disclosure.

FIG. 5 is a flowchart showing heatwave vulnerable area and vulnerable class distribution area assessment of a heatwave vulnerable area and vulnerable class distribution area assessment unit according to an embodiment of the present disclosure.

FIG. 6 is a flowchart showing spatial correlation analysis of a spatial correlation analysis unit according to an embodiment of the present disclosure.

FIG. 7 is a flowchart showing spatial relationship evaluation between a heatwave vulnerable area and a vulnerable class target facility of a spatial relationship evaluation unit between a heatwave vulnerable area and a vulnerable class target facility according to an embodiment of the present disclosure.

### DETAILED DESCRIPTION

Specific embodiments according to the present disclosure will be described below with reference to the accompanying drawings. However, this is not intended to limit the invention to any particular embodiment, and is to be understood to include all modifications, equivalents, and substitutions that fall within the idea and technical scope of the invention.

Throughout the specification, parts having like construction and operation are designated by the same reference signs. In addition, the accompanying drawings of the present disclosure are for the convenience of illustration only, and shapes and relative dimensions thereof may be exaggerated or omitted.

In describing embodiments in detail, redundant descriptions or descriptions of techniques that are obvious in the field are omitted. In addition, whenever any part is the to “include” other components in the following description, it is intended to include components in addition to those listed, unless the contrary is specifically indicated.

In addition, terms such as “part,” “section,” “module,” and the like used herein mean a unit that performs at least one function or operation, which may be implemented in hardware, software, or a combination of hardware and software. Also, when one part is the to be electrically connected to another part, this includes direct connections as well as connections with other configurations in between.

Terms containing ordinal numbers, such as first, second, and the like, may be used to describe various components, but the components are not limited by such terms. These terms are used only to distinguish one component from another. For example, a second component may be named as a first component, and similarly, a first component may be named as a second component, without departing from the scope of the present disclosure.

Exemplary embodiments will be described below in more detail with reference to the accompanying drawings. The disclosure may, however, be embodied in different forms and should not be constructed as limited to the embodiments set forth herein. Rather, these embodiments are provided so that this disclosure will be thorough and complete, and will fully convey the scope of the disclosure to those skilled in the art. Throughout the disclosure, like reference numerals refer to like parts throughout the various figures and embodiments of the disclosure.

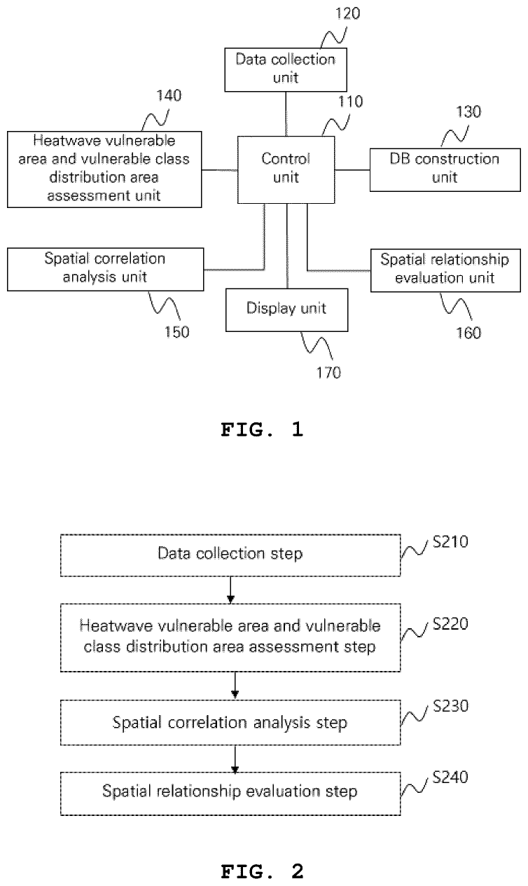

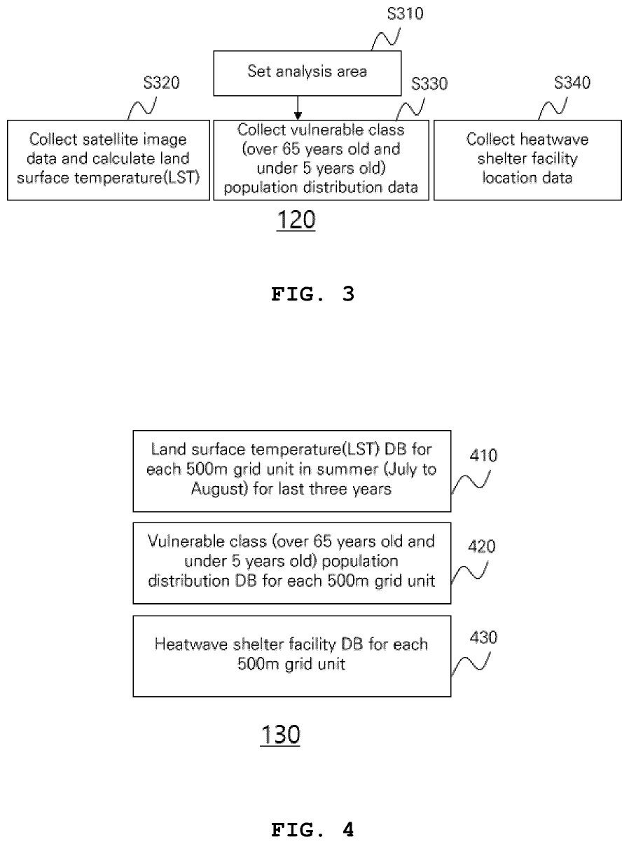

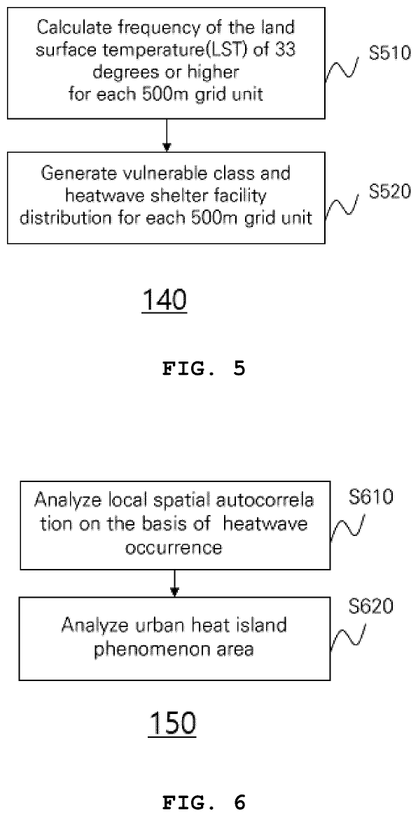

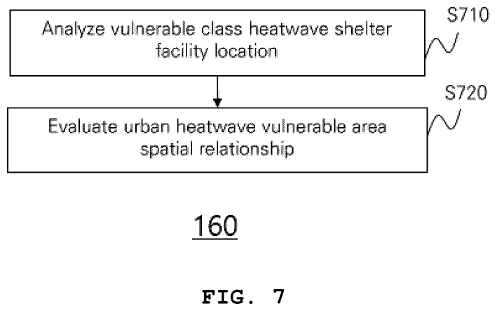

FIG. 1 is a block diagram showing a spatial relationship analyzing device for heatwave vulnerability and a vulnerable class distribution area according to an urban heat island according to an embodiment of the present disclosure. FIG. 2 is a flowchart showing spatial relationship analysis for heatwave vulnerability and a vulnerable class distribution area according to an urban heat island according to an embodiment of the present disclosure. FIG. 3 is a flowchart showing data collection of a data collection unit according to an embodiment of the present disclosure. FIG. 4 is a diagram showing an example of a DB construction unit according to an embodiment of the present disclosure. FIG. 5 is a flowchart showing heatwave vulnerable area and vulnerable class distribution area assessment of a heatwave vulnerable area and vulnerable class distribution area assessment unit according to an embodiment of the present disclosure. FIG. 6 is a flowchart showing spatial correlation analysis of a spatial correlation analysis unit according to an embodiment of the present disclosure. FIG. 7 is a flowchart showing spatial relationship evaluation between a heatwave vulnerable area and a vulnerable class target facility of a spatial relationship evaluation unit between a heatwave vulnerable area and a vulnerable class target facility according to an embodiment of the present disclosure.

The spatial relationship analyzing device for heatwave vulnerability and a vulnerable class distribution area according to an urban heat island according to the embodiment of the present disclosure includes a control unit 110, a data collection unit 120, a DB construction unit 130, a heatwave vulnerable area and vulnerable class distribution area assessment unit 140, a spatial correlation analysis unit 150, a spatial relationship evaluation unit 160, and a display unit 170.

When an analysis area is set (S310), the data collection unit 120 collects satellite image data and calculates land surface temperature LST (S320), collects distribution data of vulnerable class (e.g., over 65 years old and under 5 years old) population from a predetermined external population DB to analyze the vulnerability of a sensitive group (S330), and collects heatwave shelter facility location data from a predetermined external facility DB to analyze socioeconomic vulnerability related with heatwave (S340).

Here, the step of calculating land surface temperature LST is as follows.

Top of atmospheric spectral radiance TOA using the thermal infrared band (band 10) of satellite images is calculated according to Equation 1.

$$T O A ( L ) = {M}_{L} * Qcal + {A}_{L} \qquad [ Equation 1 ]$$

Here, L represents radiance at the top of the atmosphere, and M_{L} is a conversion coefficient assigned to each band of Landsat satellite images, Qcal is a coefficient indicating band 10 of Landsat satellite images, and A_{L} represents a conversion coefficient added for each band of Landsat satellite images.

Next, Brightness temperature BT is calculated using the Top of atmospheric spectral radiance (TOA(L)) as in Equation 2.

$$B T = \frac{K 2}{ln \frac{K 1}{L} + 1} - 273.15 \qquad [ Equation 2 ]$$

Here, K1 and K2 represent heat conversion constants, respectively.

Next, a Normalized Difference Vegetation Index NDVI is calculated using the thermal infrared band (band 4 or 5) of satellite images as in Equation 3.

$$NDVI = \frac{Band 5 - Band 4}{Band 5 + Band 4} = \frac{{ρ}_{NIR} - {ρ}_{RED}}{{ρ}_{NIR} + {ρ}_{RED}} \qquad [ Equation 3 ]$$

The Normalized Difference Vegetation Index NDVI is an index that may be used to check vegetation density and vitality by using the reflectance differences of multiple spectral bands included in Landsat satellite images, and has a range from −1 to 1. The Normalized Difference Vegetation Index NDVI shows a negative value in land cover with moisture, and shows a value close to 0 in cases where there is no vegetation. The closer the Normalized Difference Vegetation Index NDVI is closer to 1, it is meant that vegetation vitality is higher. Band 5 represents a near-infrared wavelength range among surface reflectivity ρ, and band 4 represents a red wavelength range among surface reflectivity ρ.

Next, Proportion of Vegetation Pv is calculated using the Normalized Difference Vegetation Index NDVI as in Equation 4.

$$Pv = {( \frac{NDVI - {NDVI}_{min}}{{NDVI}_{max} - {NDVI}_{min}} )}^{2} \qquad [ Equation 4 ]$$

NDVImin is a minimum NDVI value with soil only, and NDVImax is a maximum NDVI value with complete vegetation cover.

Next, Emissivity E is calculated using the Proportion of Vegetation Pv as in Equation 5.

$$ε = 0.004 * {P}_{v} + 0.986 \qquad [ Equation 5 ]$$

Finally, Land Surface Temperature LST is calculated using the Brightness temperature BT and Emissivity E as in Equation 6.

$$L S T = \frac{B T}{1 + \frac{0 \text{.00115} * BT}{1.4388} * Ln ( ε )} \qquad [ Equation 6 ]$$

Communication connection is made to any internal component or at least one any external terminal via a wired/wireless communication network. The any external terminal may include a server (not shown), a weather server (not shown), etc.

Here, wireless Internet technologies include Wireless LAN (WLAN), Digital Living Network Alliance (DLNA), Wireless Broadband (Wibro), World Interoperability for Microwave Access (Wimax), High Speed Downlink Packet Access (HSDPA), High Speed Uplink Packet Access (HSUPA), IEEE 80216, Long Term Evolution (LTE), Long Term Evolution-Advanced (LTE-A), and Wireless Mobile Broadband Service (WMBS), and data is transmitted and received according to at least one wireless Internet technology. Also, short-range communication technologies may include Bluetooth, RFID (Radio Frequency Identification), Infrared Data Association (IrDA), Ultra Wideband (UWB), ZigBee, Near Field Communication (NFC), Ultra Sound Communication (USC), Visible Light Communication (VLC), Wi-Fi, and Wi-Fi Direct. In addition, wired communication technologies may include Power Line Communication (PLC), USB communication, Ethernet, serial communication, and optical/coaxial cables.

The DB construction unit 130 stores and constructs land surface temperature data, vulnerable class population data and heatwave shelter facility number data outputted from the data collection unit 120, in a DB 410 of land surface temperature LST calculated for each grid unit of 500 m in each of length and width in the summer (July to August) of the last three years, a DB 420 of vulnerable class (over 65 years older and under 5 years old) population distributed in each grid unit, and a DB 430 of the number of heatwave shelter facilities located in each grid unit.

The DB construction unit 130 includes a storage medium, and the storage medium may include at least one of a Flash Memory Type, a Hard Disk Type, a Multimedia Card Micro Type, a memory of card type (for example, an SD or XD memory), a magnetic memory, a magnetic disk, an optical disk, a Random Access Memory (RAM), a Static Random Access Memory (SPAM), a Read-Only Memory (ROM), an Electrically Erasable Programmable Read-Only Memory (EEPROM), and a Programmable Read-Only Memory (PROM).

The heatwave vulnerable area and vulnerable class distribution area assessment unit 140 calculates the frequency of daily land surface temperature LST of 33 degrees or higher for each grid unit (S510), and generates a vulnerable class and heatwave shelter facility distribution for each grid unit (S520).

The spatial correlation analysis unit 150 analyzes local spatial autocorrelation on the basis of heatwave occurrence frequency and measures a Local Indicator of Spatial Autocorrelation (LISA) (S610), and analyzes an urban heat island phenomenon area through clustering (S620). Specifically, the spatial correlation analysis unit 150 performs local spatial autocorrelation analysis to identify in which area a spatial cluster of land surface temperature LST appears and to find different spatial patterns and abnormal areas of land prices by area.

That is to say, the local spatial autocorrelation for land surface temperature LST is to measure the Local Indicator of Spatial Autocorrelation LISA, and a local spatial autocorrelation index LS of the spatial cluster extracted through the Local Indicator of Spatial Autocorrelation LISA may be classified into four clusters (e.g., an HH cluster, an HL cluster, an LH cluster and an LL cluster).

For example, the HH cluster tends to have a high value of land surface temperature LST in a corresponding grid area and a high value of land surface temperature LST in a surrounding area, the HL cluster tends to have a high value of land surface temperature LST in a corresponding grid area and a low value of land surface temperature LST in a surrounding area, the LH cluster tends to have a low value of land surface temperature LST in a corresponding grid area and a high value of land surface temperature LST in a surrounding area, and the LL cluster tends to have a low value of land surface temperature LST in a corresponding grid area and a low value of land surface temperature LST in a surrounding area.

Here, the land surface temperature LST of a surrounding area means the average value of the land surface temperatures LST of eight grid areas surrounding a corresponding grid area as a center. When a land surface temperature LST exceeds 35 degrees Celsius, judgment is made as H, and when a land surface temperature LST is below 35 degrees Celsius, judgment is made as L.

TABLE 1

| Cluster | Point | |
|---|---|---|
| classification | distribution | Meaning |
| HH | 1.0 | Land surface temperature LST of |
| | | corresponding area is high, and land surface |
| | | temperature of surrounding area is also |
| | | high. |
| HL | 0.75 | Land surface temperature LST of |
| | | corresponding area is high, and land surface |
| | | temperature of surrounding area is low. |
| LH | 0.5 | Land surface temperature LST of |
| | | corresponding area is low, and land surface |
| | | temperature of surrounding area is high. |
| LL | 0.25 | Land surface temperature LST of |
| | | corresponding area is low, and land surface |
| | | temperature of surrounding area is also low. |

The spatial relationship evaluation unit 160 assesses the Spatial Vulnerability Index for Populations (SVP) and the Heatwave shelter facilities Location Index (SF), and then, assesses the Facilities targeting Vulnerable class Location Index (FVLI) by reflecting weights on the Spatial Vulnerability Index for Populations (SVP), the Heatwave shelter facilities Location Index (SF) and the local spatial autocorrelation index (LS).

Specifically, the Spatial Vulnerability Index for Populations (SVP) is assessed according to Equation 7.

$$SVP = \frac{( \frac{{P}_{ji}}{{p}_{jt}} )}{( \frac{{P}_{ti}}{{P}_{tt}} )} \qquad [ Equation 7 ]$$

Here, pji is the number of vulnerable population in a grid j, pjt is the total number of population in the grid j, Pti is the number of vulnerable population in an entire city, and Ptt is the total number of population in the entire city.

The Heatwave shelter facilities Location Index (SF) is assessed according to Equation 8.

$$SF = \frac{( \frac{{h}_{ji}}{{h}_{jt}} )}{( \frac{{S}_{ti}}{{S}_{tt}} )} \qquad [ Equation 8 ]$$

Here, hji is the number of vulnerable population in a grid j, hjt is the number of heatwave shelter facilities in the grid j, Sti is the number of vulnerable population in an entire city, and Stt is the number of heatwave shelter facilities in the entire city.

The Facilities targeting Vulnerable class Location Index (FVLI) is assessed according to Equation 9 and is evaluated according to Table 2.

$$FLVI = 0.3 * SVP + 0.3 * SF + 0.4 * LS \qquad [ Equation 9 ]$$

According to Table 2, the FVLI range of 0<FVLI<=0.25 represents an interest level, and it is evaluated that a corresponding grid is in a state in which the proportion of vulnerable population or vulnerable population in the corresponding grid per heatwave shelter facility is slightly higher than the level of an entire city and overall land surface temperature is low.

The FVLI range of 0.25<FVLI<=0.75 represents an attention level, and it is evaluated that a corresponding grid is in a state in which the proportion of vulnerable population or vulnerable population in the corresponding grid per heatwave shelter facility is similar to the level of an entire city and the land surface temperature of a surrounding area is relatively high.

The FVLI range of 0.75<FVLI<=1 represents a warning level, and it is evaluated that a corresponding grid is in a state in which the proportion of vulnerable population or vulnerable population in the corresponding grid per heatwave shelter facility is similar to the level of an entire city and the land surface temperature of a corresponding area is relatively high.

The FVLI range of 1<FVLI represents a risk level, and it is evaluated that a corresponding grid has higher proportion of vulnerable population than an entire city, there is a lack of heatwave shelters compared to the vulnerable population in the corresponding grid, and overall land surface temperature is high.

TABLE 2

| | Spatial relationship evaluation of urban |
|---|---|
| FVLI range | heatwave vulnerable areas |
| 0 | Excluding evaluation |
| 0 < FLVI <= 0.25 | Interest level |
| | A corresponding grid is in a state in which the |
| | proportion of vulnerable population or vulnerable |
| | population in the corresponding grid per heatwave |
| | shelter facility is slightly higher than the level of |
| | an entire city. |
| 0.25 < FLVI <= 0.75 | Attention level |
| | A corresponding grid is in a state in which the |
| | proportion of vulnerable population or vulnerable |
| | population in the corresponding grid per heatwave |
| | shelter facility is similar to the level of an entire |
| | city. |
| 0.75 < FLVI <= 1 | Warning level |
| | A corresponding grid is in a state in which the |
| | proportion of vulnerable population or vulnerable |
| | population in the corresponding grid per heatwave |
| | shelter facility is similar to the level of an entire |
| | city. |
| 1 < FLVI | Risk level |
| | A corresponding grid has higher proportion of |
| | vulnerable population than an entire city, and |
| | there is a lack of heatwave shelters compared to |
| | the vulnerable population in the corresponding |
| | grid. |

The display unit 170 displays Landsat satellite images, the Facilities targeting Vulnerable class Location Index (FVLI), weather data (e.g., temperature, humidity, barometric pressure, daily maximum temperature, etc.) for a corresponding grid collected (or received) under the control of the control unit 110.

The display unit 170 may include at least one of a liquid crystal display (LCD), a thin film transistor-liquid crystal display (TFT LCD), an organic light-emitting diode (OLED), a flexible display, a 3D display, an e-ink display, and a Light Emitting Diode (LED).

The control unit 110 may include RAM, ROM, CPU, GPU and bus, and the RAM, ROM, CPU, GPU, etc. may be connected to each other through the bus. The CPU may access the DB construction unit 130, may perform booting using the O/S stored in the DB construction unit 130, and may perform various operations using various programs, contents, data, etc. stored in the DB construction unit 130.

While various embodiments have been described above, it will be understood to those skilled in the art that the embodiments described are by way of example only. Accordingly, the disclosure described herein should not be limited based on the described embodiments.

What is claimed is:

1. A spatial relationship analyzing device for heatwave vulnerability and a vulnerable class distribution area according to an urban heat island, comprising:
a data collection unit configured to collect satellite image data to calculate land surface temperature, collect vulnerable class population distribution data from a predetermined external population DB, and collect heatwave shelter facility location data from a predetermined external facility DB;
a DB construction unit configured to store and construct land surface temperature data, vulnerable class population data and heatwave shelter facility number data outputted from the data collection unit, in a land surface temperature DB, a vulnerable class population DB and a heatwave shelter facility number DB, respectively;
a heatwave vulnerable area and vulnerable class distribution area assessment unit configured to calculate the frequency of daily land surface temperature equal to or higher than a predetermined temperature for each predetermined grid unit, and generate a vulnerable class and heatwave shelter facility distribution for the corresponding grid unit;
a spatial correlation analysis unit configured to analyze local spatial autocorrelation on the basis of heatwave occurrence frequency, and calculate a local spatial autocorrelation index; and
a spatial relationship evaluation unit configured to assess a facilities targeting vulnerable class location index using a spatial vulnerability index for populations, a heatwave shelter facilities location index and the local spatial autocorrelation index.

2. The spatial relationship analyzing device according to claim 1, wherein the facilities targeting vulnerable class location index FVLI is assessed according to the following equation
$$FLVI = 0.3 * SVP + 0.3 * SF + 0.4 * LS$$
where SVP is a spatial vulnerability index for populations, SF is a heatwave shelter facilities location index, and LS is a local spatial autocorrelation index.

3. The spatial relationship analyzing device according to claim 2, wherein the spatial vulnerability index for populations SVP is assessed according to the following equation
$$SVP = \frac{( \frac{{P}_{ji}}{{p}_{jt}} )}{( \frac{{P}_{ti}}{{P}_{tt}} )}$$
where pji is the number of vulnerable population in a grid j, pjt is the total number of population in the grid j, Pti is the number of vulnerable population in an entire city, and Ptt is the total number of population in the entire city.

4. The spatial relationship analyzing device according to claim 2, wherein the heatwave shelter facilities location index SF is assessed according to the following equation
$$SF = \frac{( \frac{{h}_{ji}}{{h}_{jt}} )}{( \frac{{S}_{ti}}{{S}_{tt}} )}$$
where hji is the number of vulnerable population in a grid j, hjt is the number of heatwave shelter facilities in the grid j, Sti is the number of vulnerable population in an entire city, and Stt is the number of heatwave shelter facilities in the entire city.

5. The spatial relationship analyzing device according to claim 2, wherein the local spatial autocorrelation index LS is assessed using land surface temperature of a corresponding grid area and land surface temperature of a surrounding grid area, and the average value of land surface temperatures of eight grid areas surrounding the corresponding grid area is assessed as the land surface temperature of the surrounding grid area.

6. A spatial relationship analyzing method for heatwave vulnerability and a vulnerable class distribution area according to an urban heat island, comprising:
a data collection act of collecting satellite image data to calculate land surface temperature, collecting distribution data of vulnerable class population from a predetermined external population DB, and collecting heatwave shelter facility location data from a predetermined external facility DB;
a DB construction act of storing and constructing land surface temperature data, vulnerable class population data and heatwave shelter facility number data generated in the data collection act, in a land surface temperature DB, a vulnerable class population DB and a heatwave shelter facility number DB, respectively;
a heatwave vulnerable area and vulnerable class distribution area assessment act of calculating the frequency of daily land surface temperature equal to or higher than a predetermined temperature for each predetermined grid unit, and generating a vulnerable class and heatwave shelter facility distribution for the corresponding grid unit;
a spatial correlation analysis act of analyzing local spatial autocorrelation on the basis of heatwave occurrence frequency, and calculating a local spatial autocorrelation index; and
a spatial relationship evaluation act of assessing a facilities targeting vulnerable class location index using a spatial vulnerability index for populations, a heatwave shelter facilities location index and the local spatial autocorrelation index.

7. The spatial relationship analyzing method according to claim 6, wherein the facilities targeting vulnerable class location index FVLI is assessed according to the following equation
$$FLVI = 0.3 * SVP + 0.3 * SF + 0.4 * LS$$
where SVP is a spatial vulnerability index for populations, SF is a heatwave shelter facilities location index, and LS is a local spatial autocorrelation index.
